(19) United States
(12) Patent Application Publication
(10) Pub. No.: US 2009/0094500 A1
(43) Pub. Date: Apr. 9, 2009

(54) Dynamic generator of unique world wide numbers

(76) Inventor: Chris Swekel, Arnold, MD (US)

Correspondence Address: JORDAN AND HAMBURG LLP, 122 EAST 42ND STREET, SUITE 4000, NEW YORK, NY, 10168, US

(21) Appl. No.: 12/287,219

(22) Filed: Oct. 6, 2008

Related U.S. Application Data
(60) Provisional application No. 60/997,801, filed on Oct. 5, 2007.

(51) Int. Cl. H03M 13/09; G06F 11/10

(52) U.S. Cl. 714/752; 714/E11.032

(57) ABSTRACT

A method and system generates World Wide Numbers for devices and LUNs which are not provided with such number. The method extracts from the devices of information data which when treated in combination is device unique. A CRC is then generated using the combination of information data. The bit length of the CRC is selected to match the WWN standard required and the CRC is used in the WWN in place of vendor.

### BACKGROUND INFORMATION

In many types of data communication and storage protocols, there exists a need for device unique identification that can be transferred between devices in a simple and expedient way. Examples of these are Fibre Channel World Wide Numbers (WWNs) that contain an IEEE defined Organizationally Unique Identifier (OUI) coupled with ANSI standard and vendor unique information and networking schemes that use MAC addresses to identify network devices in a similar way. An Organizationally Unique Identifier (OUI) is a 24-bit number that is purchased from the Institute of Electrical and Electronics Engineers, Incorporated (IEEE) Registration Authority. This identifier uniquely identifies a vendor, manufacturer, or other organization (referred to by the IEEE as the ‘assignee’) globally or worldwide and effectively reserves a block of each possible type of derivative identifier (such as MAC addresses, group addresses, Subnetwork Access Protocol identifiers, etc.) for the exclusive use of the assignee. There are also several protocols that contain device identification systems that are not everywhere unique but operate perfectly well in a well controlled and isolated environment.

Furthermore, there are devices that contain information about themselves that, when taken in aggregate, uniquely identify that device on an everywhere basis.

There exist products today that convert one communication/storage protocol to another. An example of such a product is a Fibre Channel to SATA Bridge commonly used in disk enclosures to adapt Serial Advance Technology Attachment (SATA) devices to the more flexible Fiber Channel (FCP) protocol. Problems arise when these types of conversion systems attempt to synthesize commands and data that are not adequately supported by the original protocol. An example of this is the FCP standard set of WWNs.

Typically, these systems roll numbers based on a vendor OUI and some sort of enclosure identifier. This solution provides WWNs that are unique within an individual enclosure but are not guaranteed unique from one enclosure to the next. Thus if a SATA device is removed from one enclosure and inserted into another with the different enclosure identifier, the disk will be presented in the new system with a different set of WWNs because a new WWN will be generated based on the different enclosure identifier. Conversely, if a SATA device is removed and replaced by another SATA device, the replacing SATA device will appear with the same WWNs as the original. In both cases, the requirement that the WWN be “world wide unique” for the storage device is violated. It should also be noted that this condition is undetectable.

In an attempt to solve this problem, some storage system vendors provide a service in which they uniquely stamp a set of WWNs on proprietary electronics attached to the back of the storage device, often called a dongle. While this solves the world wide unique problem within the storage vendor's storage system, it is attached to the proprietary dongle electronics and not the actual storage device (SATA Disk). Thus, if one was to separate the disk from the dongle, the unique identification is lost. It should also be noted that these types of systems are prone to human error in that one must rely on the word of the storage vendor that the number provided is indeed unique.

### SUMMARY

### Definitions

To aid in comprehension, this description may utilize examples operating under the SCSI over Fiber Channel (FCP) protocol. However, application of the present invention is not limited to such an environment is optionally applicable to any mass storage device protocol that supplies access to unique, non-volatile mass storage device identification information. Furthermore, while the disclosed embodiment of the invention is directed to mass storage devices, the present invention may be used in identifying other devices over a network for which unique identification is desirable.

The present invention is disclosed herein as applied to rotating disk devices as the most common storage medium but the invention is not limited to this application. The present invention is applicable to any random access memory device, be it rotating MR/GMR head disk, silicon based storage, or other variants of random access storage. At the time of this disclosure, the predominant storage medium used for data storage is a “disk drive”. The term “disk”, “disks”, or “disk drive” is used throughout this document as a generic label to describe a device for data storage, preferably in a random access manner.

The present invention is disclosed using ANSI standard term “WWN” (World Wide Number) to indicate an everywhere unique sequence of digits that identifies an individual storage device and data paths to it. However, this invention is applicable to any identification system that requires a unique device ID to be represented by a sequence of digits.

For purposes of definition and clarification, the aggregation of disk drive storage devices managed under a controlling intelligence is defined here as a “storage subsystem”. The controlling intelligence is identified as a “control unit”.

This invention introduces a method by which WWNs of various lengths can be generated dynamically using information provided by a storage device, or other device requiring unique identification, without the necessity of external “dongle” like attachments. The present invention ensures generation of protocol compatible WWNs that are unique and fixed to the device in question allowing tracking and identification over a heterogeneous set of vendors and enclosures of the device. The present invention includes the dynamic generation of the WWNs based on information unique to the device which is fixed to the device itself. Hence, while a WWN so generated may be stored in the device, it need not be because the information from which it is stored is fixed in the device.

The present invention provides a method of WWN generation based upon various length cyclic redundancy code (CRC) calculations taken over an aggregation of device specific information presented by the storage device. The numbers can vary from a straight 64 bit CRC to CRC's of specific length designed to fit into existing WWN standards and requirements. The device specific information is preferably data items immutable to the storage device, or whatever device is to be identified, and the scope and spirit of the present invention is considered to include use of any concatenations of such data items which are retained in the device.

In digital storage management applications, uniquely identifying storage devices and tracking their movements and/or replacement in heterogeneous storage enclosures is critical to sophisticated storage management devices. It is desirable that the risk of non-compliant or vendor unique WWN generation schemes that are prone to human error be eliminated or reduced. The present invention provides for one or more of improved reliability, vendor independence and compatibility between heterogeneous storage subsystems that use devices to convert non WWN compliant protocols to a protocol that is WWN compliant.

Briefly stated the present invention provides a method for identifying a device located at a node in a network by generating a world wide number which includes a vendor unique identifier section for the device located at a node, the method comprising extracting from the device at least first and second items of data which in combination uniquely define the device, calculating a CRC of a concatenation of the at least first and second items of data; and inserting the CRC into the vendor unique identifier section of the world wide number.

A feature of the above embodiment of the present invention includes the first and second items of data being selected from the group consisting of a vendor ID, a product identifier, and a serial number. A further optionally applied feature includes the at least first and second items of data including each of the vendor ID, the product identifier, and the serial number.

Another feature of the above embodiment of the present invention includes transferring the WWN to another device in the network in response to receiving a request from the another device.

Yet another feature of the embodiment of the invention optionally provides that the at least first and second items of data are extracted from the device via a first connection using a first protocol and the WWN is transferred to the another device via a second connection using a second protocol. In a particular optional variation of the embodiment the first protocol is SATA and the second protocol is SCSI.

A still further feature of the method of the present invention described above provides that the device is a storage device and the extracting, the calculating, and the inserting the CRC into the vendor unique identifier section is effected in a bridge device.

In a further variation of the above embodiment the present invention provides that the device is a storage device, the at least first and second items of data are transferred to the another device by a bridge device, and the extracting, the calculating, and the inserting the CRC into the vendor unique identifier section is effected in the another device which is a host unit effecting communication of data from the storage device.

In a still further variation of the above described embodiment of the invention includes transferring the WWN to another device in the network in response to a request from the another device, the device being a storage device and the extracting, the calculating, and the inserting the CRC into the vendor unique identifier section being effected in the storage device, and the at least first and second items of data being selected from the group consisting of a vendor ID, a product identifier, and a serial number. In this variation the another device is optionally a bridge device. Yet another optional feature of this variation provides that the at least first and second items of data includes each of the vendor ID, the product identifier, and the serial number.

Briefly stated another embodiment of the present invention provides a method for identifying a LUN defined in at least one storage device located at a node in a network by generating a world wide number which includes a vendor unique identifier section for the LUN located at a node, the method comprising extracting from the device at least first and second items of data which in combination uniquely define the LUN, calculating a CRC of a concatenation of the at least first and second items of data; and inserting the CRC into the vendor unique identifier section of the world wide number. Optionally provided in this embodiment is the feature that the first and second items of data are selected from the group consisting of a LUN Number, a LUN size in Blocks, LUN date created, and a LUN time created.

A further feature of the above described embodiment includes transferring the WWN to another device in the network in response to receiving a request from the another device. Still further the method provides that data from the LUN is retrieved from the at least one storage device via a first connection using a first protocol and the WWN is transferred to the another device via a second connection using a second protocol. Optionally, the first protocol is SATA and the second protocol is SCSI.

Yet another feature of the above embodiment optionally includes the extracting, the calculating, and the inserting the CRC into the vendor unique identifier section being effected in a bridge device.

Another feature of the embodiment presented above provides that the at least first and second items of data includes each of the LUN Number, the LUN size in Blocks, the LUN date created, and the LUN time created.

Still another feature of the above disclosed embodiment provides that the extracting, the calculating, and the inserting the CRC into the vendor unique identifier section is effected in the another device which is a host device connected to a bridge device over a connection using the second protocol.

The above, and other objects, features and advantages of the present invention will become apparent from the following description read in conjunction with the accompanying drawings, in which like reference numerals designate the same elements. The present invention is considered to include all functional combinations of the above described features and is not limited to the particular structural embodiments shown in the figures as examples. The scope and spirit of the present invention is considered to include modifications as may be made by those skilled in the art having the benefit of the present disclosure which substitute, for elements or processes presented in the claims, devices or structures or processes upon which the claim language reads or which are equivalent thereto, and which produce substantially the same results associated with those corresponding examples identified in this disclosure for purposes of the operation of this invention. Additionally, the scope and spirit of the present invention is intended to be defined by the scope of the claim language itself and equivalents thereto without incorporation of structural or functional limitations discussed in the specification which are not referred to in the claim language itself. Still further it is understood that recitation of the preface of “a” or “an” before an element of a claim does not limit the claim to a singular presence of the element and the recitation may include a plurality of the element unless the claim is expressly limited otherwise. Yet further it will be understood that recitations in the claims which do not include “means for” or “steps for” language are not to be considered limited to equivalents of specific embodiments described herein.

### BRIEF DESCRIPTION OF THE DRAWINGS

FIG. 1 is a block diagram of an embodiment of a system configuration for implementation of the present invention; and

FIG. 2 is a flow chart of a process for generating WWNs for disks in an implementation of the present invention.

FIG. 3 is a flow chart of a process for generating WWNs for LUNs in an implementation of the present invention.

### DETAILED DESCRIPTION

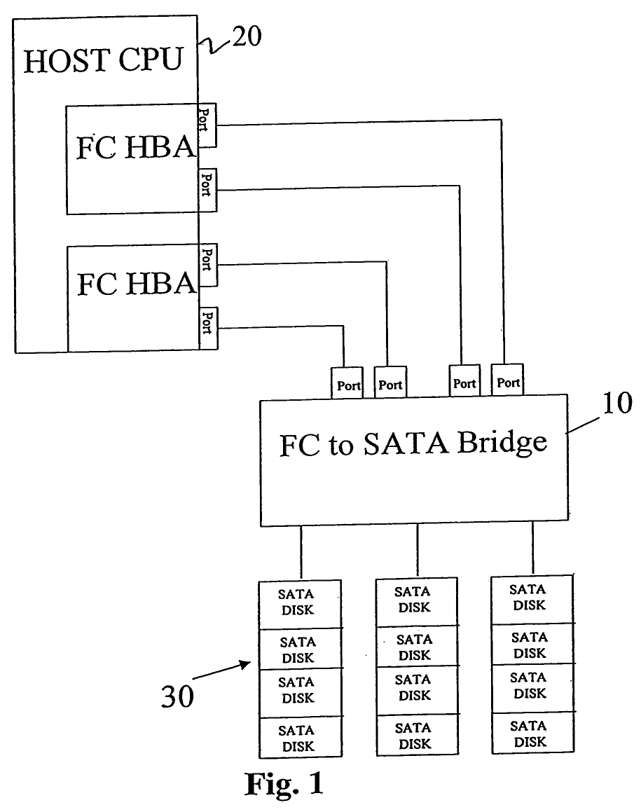

Referring to FIG. 1, an example configuration of a system applying the present invention is shown. The present invention is described based on an application using a multi-ported Fibre Channel (FC) to SATA bridge controller 10 connected to multiple ports of a host computer unit 20 that is WWN aware. This host computer unit 20 be any type of WWN aware control unit which is used to interface with other unit requiring data to be retrieved. The FC to SATA bridge controller 10 is assumed to provide one of the limited WWN conversion schemes mentioned above. The FC to SATA bridge controller 10 connects to SATA disks 30. It is understood that the FC to SATA bridge controller 10 and the SATA disks 30 are exemplary and are intended to represent respectively a ported interface device and devices attached to nodes interfaced by the ported interface device to the ports thereof. It is further understood that a disk controller may be added between the FC to SATA bridge controller 10.

### WWN Generation Example

This example provides a high level description of a WWN generation scheme that conforms to the SCSI standard for NAA type 2 and the IEEE extended WWN. This number is unique to the SATA device regardless of the FC to SATA converter attached. In this case, it is assumed that the FC to SATA bridge 10 provides SCSI standard information based on the following translation between SCSI and SATA commands.

TABLE 1
SATA to SCSI Mapping

| SCSI Data Element | SATA Data Element |
|---|---|
| Standard Inquiry Data - | First word of the Model Number field of |
| Vendor ID | the Identify Device data |
| Standard Inquiry Data - | Next 16 characters after the first word of |
| Product Identifier | the Model Number field of the Identify |
| | Device data |
| Vital Product Data Page 80h - | Serial Number field of the Identify |
| Serial Number | Device data |

The translation SATA standard data and commands to SCSI standard data related above is exemplary of a translation approach which is optionally utilized in the implementation of the present invention. The present invention is not considered limited to the translation approach and it is realized that other translation approaches may be realized by those skilled in the art in light of the present disclosure. The exemplary approach suffices to show that sufficient information is present in the native device for translation into a WWN compliant protocol to identify the device uniquely.

In this scheme a 24 Bit CRC will be used to consolidate the device unique information listed in the table above into a 24 bit value that will be stored into the vendor unique section of the NAA type 2 device unique identifier and the IEEE extended format WWNs. It is assumed in this example that the FC to SATA bridge device 10 provides numbers according to these standards. These numbers are provided to the host 20. The 24 bit CRC data will be substituted in place of the 24 bits of vendor unique data generated by the FC to SATA Bridge 10 to provide a device unique replacement for the otherwise suspect original.

In accordance with the above, in the preferred embodiment as discussed below the FC to SATA Bridge 10 queries and collects the device unique information from respective ones of the SATA disks 30 and generates the 24 bit value for use in the vendor unique section of the NAA type 2 device unique identifier and the IEEE extended format WWNs, and then provides the value to the host 20 to identify the given one of the SATA disks 30. This 24 bit value may be save in memory of the FC to SATA Bridge 10 for the particular associated one of the SATA disks 30 or generated on the fly by the FC to SATA Bridge 10. In either case the 24 bit value is used to uniquely identify the particular one of the SATA disks 30. It is understood that the FC to SATA bridge receives the unique data from the SATA disk 30 being queried and takes this data received from the SATA disk, applies the 24 bit CRC in a manner further detailed below, generates the WWN and presents it in SCSI compatible format to the host 20. The FC to SATA bridge 10 can present the WWNs via the standard mechanism provided by the Fiber Channel specification applicable.

It will be recognized by those skilled in the art of storage system design, that each of the SATA disks 30, the FC to SATA Bridge 10, and the Host 20 will have access to the same unique data stored in the SATA disks 30, and that any of these three elements of the system may implement the method of the present invention to generate a unique WWN for the particular one of the SATA disks 30. For example a SATA disk unit 30 contains the unique data and may itself be configured to generate the unique WWN and provide it to the FC to SATA Bridge 10.

It will still further be evident to those skilled in the art in light of this disclosure that the host 20 may query the unique data from the SATA disk 30 via the FC/SATA bridge 10 and generate a WWN to associate with the SATA disk 30 using the 24 bit CRC in a manner as detailed below. It will be understood by those skilled in the art that each of the elements shown, the SATA disks 30, the FC/SATA bridge 10, and the host 20 have onboard computing intelligence sufficient to be configured to implement the method of the present invention and details of such configurations are thus omitted as being readily implementable by those skilled in the art having the benefit of this disclosure.

### Synthesis of Node Name

Node Names in this example have the following format:

TABLE 2
IEEE Extended Identifier Format (Node Name)

| NAA | VSID | | ULA | |
|---|---|---|---|---|
| 4 bits | 10 bit VIDA | 2 bit PNN | 24 bit OUI | 24 bit VIDB |
| 0010 | xxxxxxxxxx | 00 | yyyyyyyyyyyyyyyyyyyyyyyy | zzzzzzzzzzzzzzzzzzzzzzzz |

The process for generating the Node Name is as follows:
1. Collect the device identification data. For example, a Maxtor 250 GB SATA would have the following data:

| Inquiry Data Field | Field Contents | HEX Values |
|---|---|---|
| Vendor ID | “Maxtor” | 4D6178746F722020 |
| Product Identifier | “7Y250M0 ” | 37593235304D30202020202020202020 |
| Serial Number | “Y650HWQE ” | 5936353048575145202020202020202020202020 |

The above Inquiry Data Fields are exemplary and the invention is not considered limited to those specific field unless otherwise stated in the claims. Other types of data fields which are stored in a device may be used in place of the above noted fields or in addition to the above noted fields.
2. Calculate a 24 bit CRC over a concatenation of this data. For example, using the Maxtor device identification data, in standard C the data can be stored in an unsigned character array:

$$unsigned char crcBuf [ ] = \{ 0 \times 4 D , 0 \times 61 , 0 \times 78 , 0 \times 74 , 0 \times 6 F , 0 \times 72 , 0 \times 20 , 0 \times 20 , 0 \times 37 , 0 \times 59 , 0 \times 32 , 0 \times 35 , 0 \times 30 , 0 \times 4 D , 0 \times 30 , 0 \times 20 , 0 \times 20 , 0 \times 20 , 0 \times 20 , 0 \times 20 , 0 \times 20 , 0 \times 20 , 0 \times 20 , 0 \times 20 , 0 \times 59 , 0 \times 36 , 0 \times 35 , 0 \times 30 , 0 \times 48 , 0 \times 57 , 0 \times 51 , 0 \times 45 , 0 \times 20 , 0 \times 20 , 0 \times 20 , 0 \times 20 , 0 \times 20 , 0 \times 20 , 0 \times 20 , 0 \times 20 , 0 \times 20 , 0 \times 20 , 0 \times 20 , 0 \times 20 \}$$

This array is then passed as an argument to the CRC generating function, which also takes as an argument the length of the array:

myCRC=crc24(crcBuf,44);
3. The resulting 24 bits in myCRC is then substituted for the 24 bits of vendor unique data (VIDB) presented in the node name generated by the FC to SATA bridge for the device.

### Synthesis of Port Name

Port names in this example have the following format:

TABLE 2
IEEE Extended Identifier Format (Port Name)

| NAA | VSID | | ULA | |
|---|---|---|---|---|
| 4 bits | 10 bit VIDA | 2 bit PNN | 24 bit OUI | 24 bit VIDB |
| 0010 | xxxxxxxxxx | nn | yyyyyyyyyyyyyyyyyyyyyyyy | zzzzzzzzzzzzzzzzzzzzzzzz |

In this example, generation of the Port Name follows the same process as the Node Name (the Port identifier is contained in bits “nn” and is already provided for by the FC to SATA bridge).

### Synthesis of Lun WWN

LUN Names, although rarely used by contemporary control units, can also be generated in the same way. For example, if the FC/SATA Bridge 10 provides some sort of abstraction in which groupings of individual SATA drives 10 can be presented to the HBA of the host 20 as Logical Units, it is possible to construct unique WWNs for each of these LUNs.

For purposes of illustration, suppose we would like to generate World Wide LUN names conforming to the following IEEE standard format:

TABLE 3
IEEE Registered Extended Identifier Format (LUN Name)

| | | | Vendor Specified |
|---|---|---|---|
| NAA | IEEE Company Id | Vendor Specified ID | ID Extension |
| 4 bits | 24 bit OUI | 36 bit VSID | 64 bit VSIDE |
| 0110 | xxxx . . . xxxx | yyyy . . . yyyy | zzzz . . . zzzz |

Assuming the FC/SATA bridge 10 conforms to the IEEE Registered format for Node names, the LUN name can be generated as follows:
(1) OUI=24 Bit Organizationally Unique Identifier from Node Name.
(2) VSID=12 Bit Vendor Specified ID from the Node Name concatenated with the 24 bit VIDB from Node Name.
(3) VSIDE=64 bit CRC generated over an aggregation of LUN specific parameters (Lun Number, Size in Blocks, Date Created, Time Created).

For example, a Bridge that concatenates five Maxtor 250 GB SATA drives into two Logical Units might have the following data for each LUN:

| | | |
|---|---|---|
| Data Field | Field Contents | HEX Values |

Logical Unit 0

| | | |
|---|---|---|
| OUI | 00909F | 00909F |
| VSID | A337A4E3F | 0A337A4E3F |
| LUN Number | 0 | 00 |
| Size in Blocks | 1464843750 | 574FBDE6 |
| Date Created | July 1, 2005 at 3:23:01 | 42C4B715 |

Logical Unit 1

| | | |
|---|---|---|
| OUI | 00909F | 00909F |
| VSID | A337A4E3F | 0A337A4E3F |
| LUN Number | 1 | 01 |
| Size in Blocks | 976562500 | 3A352944 |
| Date Created | July 1, 2005 at 3:55:32 | 42C4BEB4 |

As in the prior example, the above Data Fields, i.e., LUN parameters, are exemplary and the invention is not considered limited to those fields unless otherwise stated in the claims. Other types of data fields which are stored in a device or associated with a LUN may be used in place of the above noted fields or in addition to the above noted fields.

The HEX Value representation for Date Created preferably conforms to the Unix standard numerical representation of seconds since standard epoch of Jan. 1, 1970. However, one skilled in the art will recognize that other representations may be adopted.

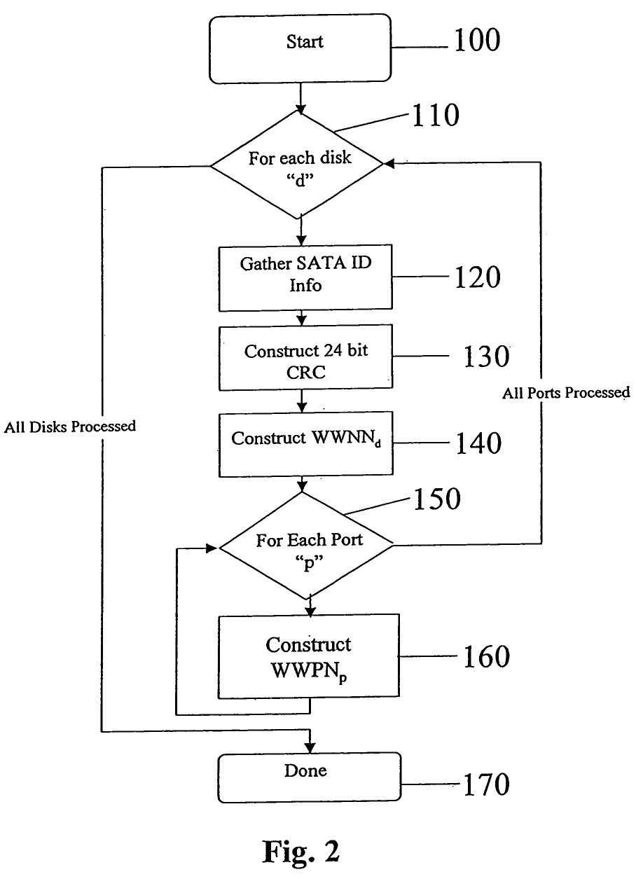

Referring to FIG. 2, a high level flow chart presents an exemplary processing method for the present invention which is executed optionally by either the host computer 20, a disk controller unit employed between the host computer 20 and the FC to SATA bridge controller 10, or within the FC to SATA bridge controller 10. The process begins at the start 100 and proceeds to check for disks to be identified at decision step 110. As long as disks remain to be identified the process proceeds to step 120 wherein the aforementioned SATA ID data of Table 1 is retrieved from respective ones of the disks 30 via the FC to SATA bridge 20. In step 130 a 24 Bit CRC is calculated using the SATA ID data. In step 140, the calculated CRC code is used to construct the WWN for the disk d at the respective node with the result being WWNN_{d}. At decision step 150 it is decided whether each port associated with the disk d has had a WWN associated with it determined. If not, a WWN for the port is constructed at step 160 using the 2 bit Port Name Number provided by the FC to SATA bridge 30. The WWN for each port is denoted WWPNₚ. Following construction of the WWPNₚ the processing returns to decision step 150 whereat it is determined whether there are further ports associated with the given disk d for which a WWN need be constructed. If all ports are addressed for the given disk d the process returns to decision step 110 whereat it is determined if further disks remain to have a WWN calculated for them. If further disks remain, the above processing is repeated. If all disks have been processed, the process proceeds to end at step 170.

It will be realized by those skilled in that art that the steps involved in the above processing may be executed in different orders, and that other processing algorithms may be employed having different structures. The scope and spirit of the present invention is intended to include such modifications provided that device unique data is extracted from devices at nodes and the a CRC code is generated using the device unique data to provide a basis for a WWN for the device.

Using the same technique described above we can calculate two 64 bit CRCs (one for each LUN) by first arranging the data into two arrays:

$$unsigned char crcBufLun 0 ] [ ] = \{ 0 \times 00 , 0 \times 90 , 0 \times 9 F , 0 \times 0 A , 0 \times 33 , 0 \times 7 A , 0 \times 4 E , 0 \times 3 F , 0 \times 00 , 0 \times 57 , 0 \times 4 F , 0 \times DB , 0 \times E 6 , 0 \times 42 , 0 \times C 4 , 0 \times B 7 , 0 \times 15 \} ; \\ unsigned char crcBufLun 11 ] [ ] = \{ 0 \times 00 , 0 \times 90 , 0 \times 9 F , 0 \times 0 A , 0 \times 33 , 0 \times 7 A , 0 \times 4 E , 0 \times 3 F , 0 \times 01 , 0 \times 3 A , 0 \times 35 , 0 \times 29 , 0 \times 44 , 0 \times 42 , 0 \times C 4 , 0 \times BE , 0 \times B 4 \} ;$$

Then calculating a 64 bit CRC for each using well known CRC generation techniques:

myCRCLun0=crc64(crcBufLun0,17);

myCRCLun1=crc64(crcBuJLun1,17);

And finally using the resulting 64 bit number to represent each LUN's 64 bit Vendor Specified ID Extension (VSIDE).

Those skilled it the art understand that the NUM WWN is required by the “Fibre Channel Protocol for SCSI Specification” under “Use of World Wide Names” (Section 5.2, FCP-3, rev 3a) which is hereby incorporated by reference for its disclosure of allowed formats which are applicable to the present invention. It will be further realized by those skilled in the art that the present invention may be adapted to identifying systems which require bit lengths different from those presented above by using differing bit length CRC operations.

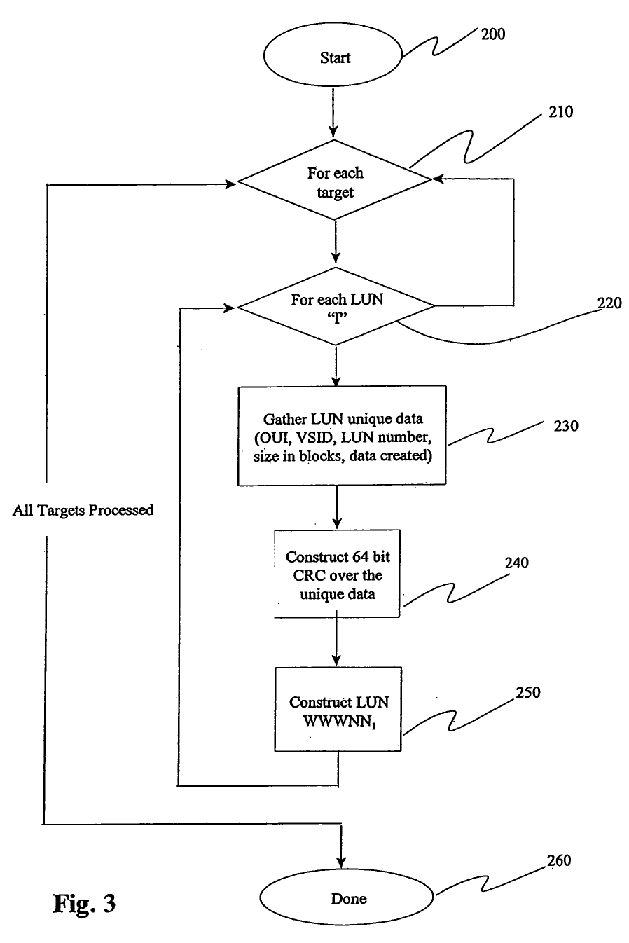

Referring to FIG. 3, a flow chart describes one possible procedure for generating WWNs for LUNs. This type of operation would generally be done inside a virtualization device like a RAID controller, a bridge such as the FC/SATA bridge 10 or even a storage switch. Any device that aggregates multiple storage elements, such as disk drives, into a larger virtual element like a virtual disk or target with multiple Logical Units (LUNs) may utilize the method of this invention for generating WWNs for the LUNs. The process begins at the start 200 and proceeds to a looping decision block 210 which decides whether all targets have been considered. When all targets have not been considered the process proceeds to decision block 220 wherein it is decided whether all LUNs for each target have been addressed. If all LUNs are addressed are addressed for a given target the process returns to decision block 210. If all LUNs are not address the process proceeds to execute step 230, 240 and 250 wherein the WWN is generated for each LUN identified by the incremented variable I. In step 230 the LUN unique data discussed above is gathered. Next in step 240, a 64 bit CRC over the concatenated unique data is generated. In step 250, the 64 bit CRC is inserted as shown in the above description to create the WWNN₁ for LUN₁. The process returns to decision block 220 wherein it is determined if all LUNs for a given target have been given a WWN. Once all LUNs for a given target are given a WWN, the process returns to decision block 210 wherein it is determined whether each target is addressed. When all targets are addressed the process ends at step 260. Thus the process is applied to situation wherein there are multiple targets, such as plural RAID controllers wherein each has configured multiple LUNs. If multiple targets do not exist, the process may be simply limited to considering multiple LUNs of a single target.

### Advantages.

1. Through the use of this invention it is possible to generate device specific and world wide unique identifiers based on an aggregation of information already present in the native storage device.
2. This invention guarantees a memoryless and reproducible generation of numbers of arbitrary length that can be used to synthesize a variety of standard device unique identification schemes.
3. Through this invention, control units can safely identify and track storage devices without the reliance on vendor unique and storage device external solutions.
4. Through this invention, control units can safely identify and track storage devices over heterogeneous sets of enclosures.

While particular embodiments of the present invention have been shown and described, it will be appreciated by those skilled in the art that, based upon the teachings herein, changes and modifications may be made without departing from this invention and its broader aspects and, therefore, the appended claims are to encompass within their scope all such changes and modifications as are within the true spirit and scope of this invention. The true spirit and scope is considered to encompass devices and processes, unless specifically limited to distinguish from known subject matter, which provide equivalent functions as required for interaction with other elements of the claims and the scope is not considered limited to devices and functions currently in existence where future developments may supplant usage of currently available devices and processes yet provide the functioning required for interaction with other claim elements. Furthermore, it is to be understood that the invention is solely defined by the appended claims. It is understood by those with skill in the art that unless a specific number of an introduced claim element is recited in the claim, such claim element is not limited to a certain number. For example, introduction of a claim element using the indefinite article “a” or “an” does not limit the claim to “one” of the element. Still further, the following appended claims can contain usage of the introductory phrases “at least one” and “one or more” to introduce claim elements. Such phrases are not considered to imply that the introduction of a claim element by the indefinite articles “a” or “an” limits any particular claim containing such introduced claim element to inventions containing only one such element, even when the same claim includes the introductory phrases “one or more” or “at least one” and indefinite articles such as “a” or “an”; similarly, the use in the claims of definite articles does not alter the above related interpretation indefinite articles such as “a” or “an”.

This application claims priority to provisional application 60/997,801, filed Oct. 5, 2007, and said provisional application is hereby incorporated by reference into this specification for purposes of describing and enabling the claimed invention in any manner that is not addressed by the present specification.

What is claimed is:

1. A method for identifying a device located at a node in a network by generating a world wide number which includes a vendor unique identifier section for the device located at a node, comprising:
extracting from said device at least first and second items of data which in combination uniquely define the device;
calculating a CRC of a concatenation of the at least first and second items of data; and
inserting the CRC into the vendor unique identifier section of the world wide number.

2. The method of claim 1 wherein said first and second items of data are selected from the group consisting of a vendor ID, a product identifier, and a serial number.

3. The method of claim 2 wherein said at least first and second items of data includes each of said vendor ID, said product identifier, and said serial number.

4. The method of claim 3 further comprising transferring the WWN to another device in the network in response to receiving a request from the another device.

5. The method of claim 4 wherein said at least first and second items of data are extracted from said device via a first connection using a first protocol and the WWN is transferred to said another device via a second connection using a second protocol.

6. The method of claim 5 wherein said first protocol is SATA and the second protocol is SCSI.

7. The method of claim 6 wherein said device is a storage device and said extracting, said calculating, and said inserting the CRC into the vendor unique identifier section is effected in a bridge device.

8. The method of claim 2 wherein said at least first and second items of data are extracted from said device via a first connection using a first protocol and transferred to another device via a second connection using a second protocol.

9. The method of claim 8 wherein said first protocol is a SATA protocol and the second protocol is SCSI.

10. The method of claim 9 wherein said device is a storage device, said at least first and second items of data are transferred to said another device by a bridge device, and said extracting, said calculating, and said inserting the CRC into the vendor unique identifier section is effected in said another device which is a host unit effecting communication of data from said storage device.

11. The method of claim 10 wherein said at least first and second items of data includes each of said vendor ID, said product identifier, and said serial number.

12. The method of claim 1 further comprising:
transferring the WWN to another device in the network in response to a request from the another device;
said device is a storage device and said extracting, said calculating, and said inserting the CRC into the vendor unique identifier section is effected in said storage device; and
said at least first and second items of data are selected from the group consisting of a vendor ID, a product identifier, and a serial number.

13. The method of claim 12 wherein said another device is a bridge device.

14. The method of claim 13 wherein said at least first and second items of data includes each of said vendor ID, said product identifier, and said serial number.

15. A method for identifying a LUN defined in at least one storage device located at a node in a network by generating a world wide number which includes a vendor unique identifier section for the LUN located at a node, comprising:
extracting from said device at least first and second items of data which in combination uniquely define the LUN;
calculating a CRC of a concatenation of the at least first and second items of data; and
inserting the CRC into the vendor unique identifier section of the world wide number.

16. The method of claim 15 wherein said first and second items of data are selected from the group consisting of a LUN Number, a LUN size in Blocks, LUN date created, and a LUN time created.

17. The method of claim 16 further comprising transferring the WWN to another device in the network in response to receiving a request from the another device.

18. The method of claim 17 wherein data from said LUN is retrieved from said at least one storage device via a first connection using a first protocol and the WWN is transferred to said another device via a second connection using a second protocol.

19. The method of claim 18 wherein said first protocol is SATA and the second protocol is SCSI.

20. The method of claim 18 wherein said extracting, said calculating, and said inserting the CRC into the vendor unique identifier section is effected in a bridge device.

21. The method of claim 20 wherein said at least first and second items of data includes each of said LUN Number, said LUN size in Blocks, said LUN date created, and said LUN time created.

22. The method of claim 18 wherein said extracting, said calculating, and said inserting the CRC into the vendor unique identifier section is effected in said another device which is a host device connected to a bridge device over a connection using said second protocol.

23. The method of claim 22 wherein said at least first and second items of data includes each of said LUN Number, said LUN size in Blocks, said LUN date created, and said LUN time created.
